(19) United States
(12) Patent Application Publication
(10) Pub. No.: US 2015/0171296 A1
(43) Pub. Date: Jun. 18, 2015

(54) LIGHT EMITTING PACKAGE AND CARRIER STRUCTURE THEREFOR

(71) Applicant: Lee-Sheng Yen, Yaoyuan City (TW)

(72) Inventor: Lee-Sheng Yen, Yaoyuan City (TW)

(21) Appl. No.: 14/256,498

(22) Filed: Apr. 18, 2014

(30) Foreign Application Priority Data
Dec. 12, 2013 (TW) 102223444

(51) Int. Cl. H01L 33/62; H05K 1/02; H01L 33/64

(52) U.S. Cl. CPC H01L 33/62; H01L 33/644; H05K 1/02

(57) ABSTRACT

A light emitting package is provided, including a plurality of conductive traces, an insulative portion combined with the conductive traces to form a packaging substrate, a receiving body formed on the packaging substrate and having an opening for the first surfaces of the conductive traces to be exposed therefrom, a light emitting member disposed on the substrate via the opening and electrically connected with the conductive traces, and an encapsulant formed in the opening to encapsulate the light emitting member. The conductive traces combined with the insulative portion are used to carry the light emitting member, allowing the light emitting package to thus meet the low-profile requirement and the heat transmission efficiency to be greatly enhanced.

### BACKGROUND OF THE INVENTION

1. Field of the Invention

The present invention relates to semiconductor packages, and, more particularly to a light emitting package and a carrier structure therefor.

2. Description of the Prior Art

As the technology for developing electronic products is steadily growing, the trend of electronic products has now moved towards low profile, high functionality and high operational speed. Light emitting diode (LED) has the advantages of long life, small size, high resistance to shock, and high energy efficiency, and therefore has been widely used in electronic products requiring illumination, to be used in the industry, incorporated in various electronic products or in home appliances.

FIG. 1 is a cross-sectional view of a conventional LED package 1. The LED package 1 has a reflector 11 having an opening 110 and disposed on a lead frame 10. An LED element 12 is disposed in the opening 110. A plurality of bonding wires 120 electrically connect the lead frame 10 and the LED element 12. An encapsulant 13 is formed in the opening 110 to encapsulate the LED element 12 and the bonding wires 120.

Since the conventional LED package 1 utilizes the lead frame 10 as the carrier of the LED element 12, which is at least 0.2 mm in thickness, it makes the LED package 1 too thick to be a desirable candidate as a satisfactory low profile package.

Moreover, the thermal resistance is correlated with the thickness of the package. In specific, the thinner the package is, the less the heat resistance becomes, and the heat transmission is more efficient, as described in R=L/kA (R is heat resistance; K is the transmission distance, i.e., the thickness L of the lead frame; A is the heat transmission area; k is the heat transmission coefficient). Since the overall thickness of the LED package 1 cannot be reduced due to the lead frame 10, the heat resistance also cannot be lowered further, and, as a result, the heat transmission rate cannot be improved.

Therefore, there is an urgent need in solving the foregoing problems.

### SUMMARY OF THE INVENTION

In light of the foregoing drawbacks of the prior art, the present invention provides a carrier structure, comprising: a plurality of conductive traces each having a first surface, a second surface opposing the first surface, and a side surface abutting the first and second surfaces; an insulative portion combined with the conductive traces to form a packaging substrate; and a receiving body formed on the packaging substrate and having an opening for the first surfaces of the conductive traces to be exposed therefrom.

The present invention further provides a light emitting package, comprising: a plurality of conductive traces each having a first surface, a second surface opposing the first surface, and a side surface abutting the first and second surfaces; an insulative portion combined with the conductive traces to form a packaging substrate; a receiving body formed on the substrate and having an opening for the first surfaces of the conductive traces to be exposed therefrom; at least a light emitting member disposed on the substrate via the opening and electrically connected with the conductive traces; and an encapsulant formed in the opening to encapsulate the light emitting member.

In the light emitting package and the carrier structure, the conductive traces combined with the insulative portion are used to carry the light emitting diode thereon. Therefore, the lead frame provided by the conventional technology is omitted, and the light emitting package and the carrier structure meet the low profile requirement, and the heat transmission efficiency is also enhanced.

Moreover, the design of the insulative portion combined with the conductive traces further strengthen the structural integrity to support the light emitting members.

### BRIEF DESCRIPTION OF THE DRAWINGS

The present invention can be more fully understood by reading the following detailed description of the preferred embodiments, with reference made to the accompanying drawings, wherein:

FIG. 1 is a cross-sectional view of a conventional LED package.

FIGS. 2A-2E are schematic cross-sectional views of different types of light emitting packages in accordance with a first preferred embodiment of the present invention, wherein FIGS. 2B and 2D refer to the other type of the light emitting package of FIGS. 2A and 2C.

FIGS. 3A-3C are schematic cross-sectional views of different types of light emitting packages in accordance with a second preferred embodiment of the present invention.

FIG. 4 is a schematic cross-sectional view of a light emitting package in accordance with a third preferred embodiment of the present invention.

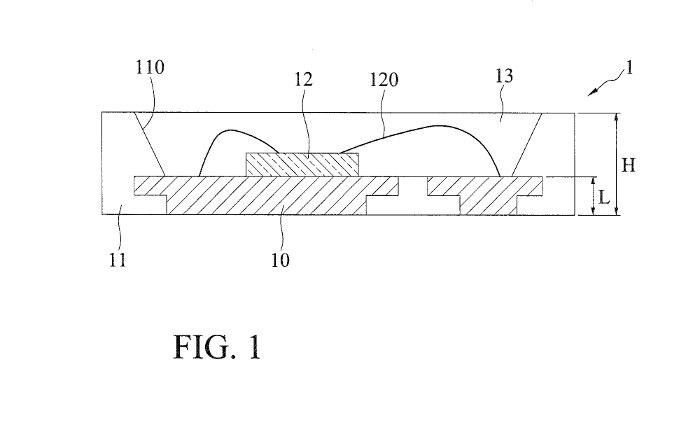

### DETAILED DESCRIPTION OF THE INVENTION

The present invention is described in the following with specific embodiments, so that one skilled in the pertinent art can easily understand other advantages and effects of the present invention from the disclosure of the present invention.

It is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements. In addition, words such as “on,” “top” and “a” are used to explain the preferred embodiment of the present invention only and should not limit the scope of the present invention.

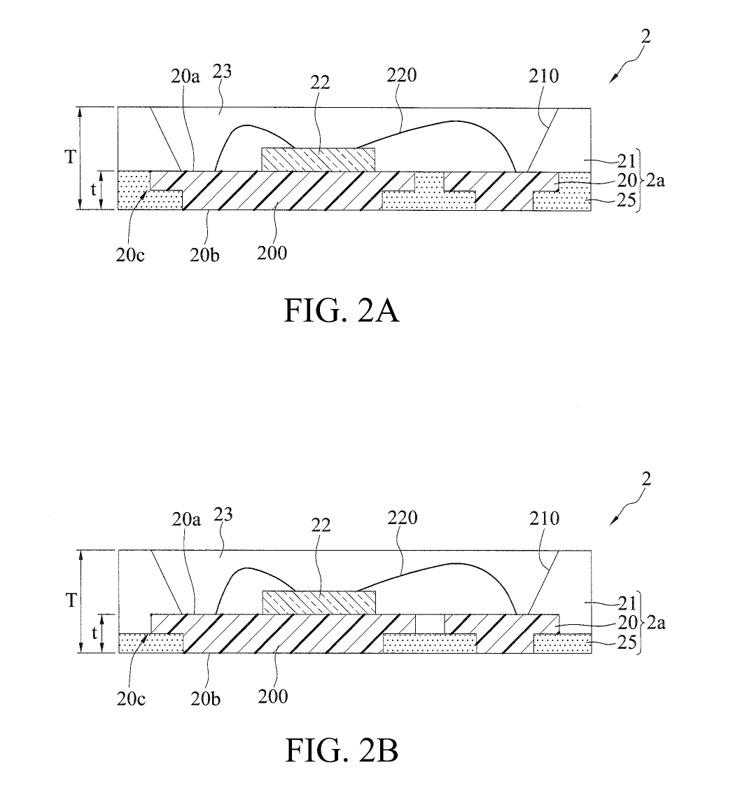

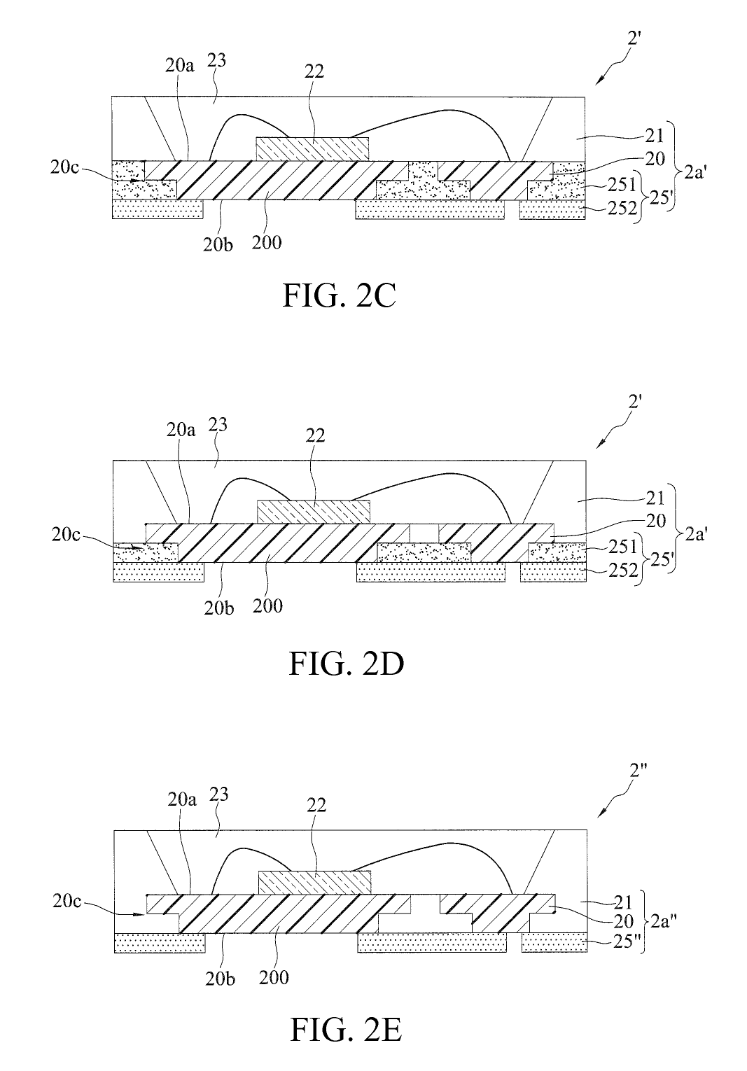

FIGS. 2A-2E are schematic cross-sectional views of different types of light emitting packages in accordance with a first preferred embodiment of the present invention. The light emitting package 2, 2′, 2″ comprises: a carrier structure 2a, 2a′, 2a″ (comprising a plurality of conductive traces 20, an insulative portion 25, 25′, 25″, and a receiving body 21, an light emitting member 22, and an encapsulant 23.

The conductive traces 20 each has a first surface 20a, a second surface 20b opposing the first surface 20a, and a side surface 20c abutting the first surface 20a and the second surface 20b. The conductive traces 20 each is in a convex-concave structure (the same as the convex part 200 of the second surface 20b). The conductive traces 20 are made of a conventional material applicable to form the circuits of the circuit board, such as metal (commonly, copper). The variety of applicable materials is large and is not specifically limited.

In the carrier structure 2a shown in FIG. 2A, the insulative portion 25 is attached to the side surface 20c of each of the conductive traces 20, for exposing the convex part 200 of the second surface 20b of each of the conductive traces 20. The insulative portion 25 is made of an insulative material such as silicon, or epoxy of white, black or other color. The dielectric material is epoxy resin containing glass fiber/cloth. The insulative portion 25 can be made of dielectric material or solder mask material.

The receiving body 21 is formed on the insulative portion 25 and a portion of the first surface 20a of each of the conductive traces 20, and has an opening 210 for the first surfaces 20a to be exposed therefrom, such that the receiving body 21 acts as a reflector. In an embodiment, the receiving body 21 is made of silicon or epoxy resin without containing glass fibers.

The light emitting member 22 is disposed on a packaging substrate formed by the conductive traces 20 combined with the insulative portion 25 via the opening 210 of the first surface 20a, and is electrically connected to the conductive traces 20 via a plurality of bonding wires 220.

The insulative portion 25′ of the carrier structure 2a′ shown in FIG. 2C comprises an insulative layer 251 and a second insulative layer 252. The first insulative layer 251 is attached to the side surfaces 20c of the conductive traces 20. The second insulative layer 252 is attached to the second surfaces 20b of the conductive traces 20.

The first insulative layer 251 is made of a dielectric material such as epoxy resin containing glass fibers or cloth. The second insulative layer 252 is a solder mask layer.

As shown in FIG. 2E, the insulative portion 25″ is made of a solder mask material and attached to a part of the second surface 20b of the conductive trace 20. The receiving body 21 is formed on the insulative portion 25″ and a portion of the first surfaces 20a of the conductive traces 20, and attached to the overall side surfaces 20c of the conductive traces 20.

As shown in FIGS. 2B and 2D, the receiving body 21 is attached to a portion of the side surfaces 20c of the conductive traces 20, allowing the insulative portion 25, 25′ to be attached to the side surfaces 20c of the convex parts 200 of the conductive traces 20.

In an embodiment, the conductive traces 20 and the insulative portion 25, 25′, 25″ are fabricated under the substrate process, by using the conductive traces 20 combined with the insulative portion 25, 25′, or 25″ as the carrier of the light emitting member 22. Since the thickness t of each of the conductive traces 20 is very small (0.035 mm), the overall thickness T (at least 0.325 mm) of the light emitting package 2, 2′, 2″ can be reduced, thereby desirably achieving the low profile requirement.

Moreover, since the thickness of each of the conductive traces 20 can be reduced according to the requirement, the heat resistance can also be reduced, so as to increase the heat transmission efficiency.

In addition, supporting strength of the packaging substrate formed by the conductive traces 20 combined with the insulative portion 25, 25′, 25″ to carry the light emitting member 22 is greatly enhanced through secured attachment to the insulative portion 25, 25′, 25″ against the side surfaces 20c of the conductive traces 20.

Furthermore, since the insulative portion 25, 25′, 25″ contains a solder mask material, moist can be prevented from entering the receiving body 21, and therefore it is possible to prevent the inner circuits from corrosion.

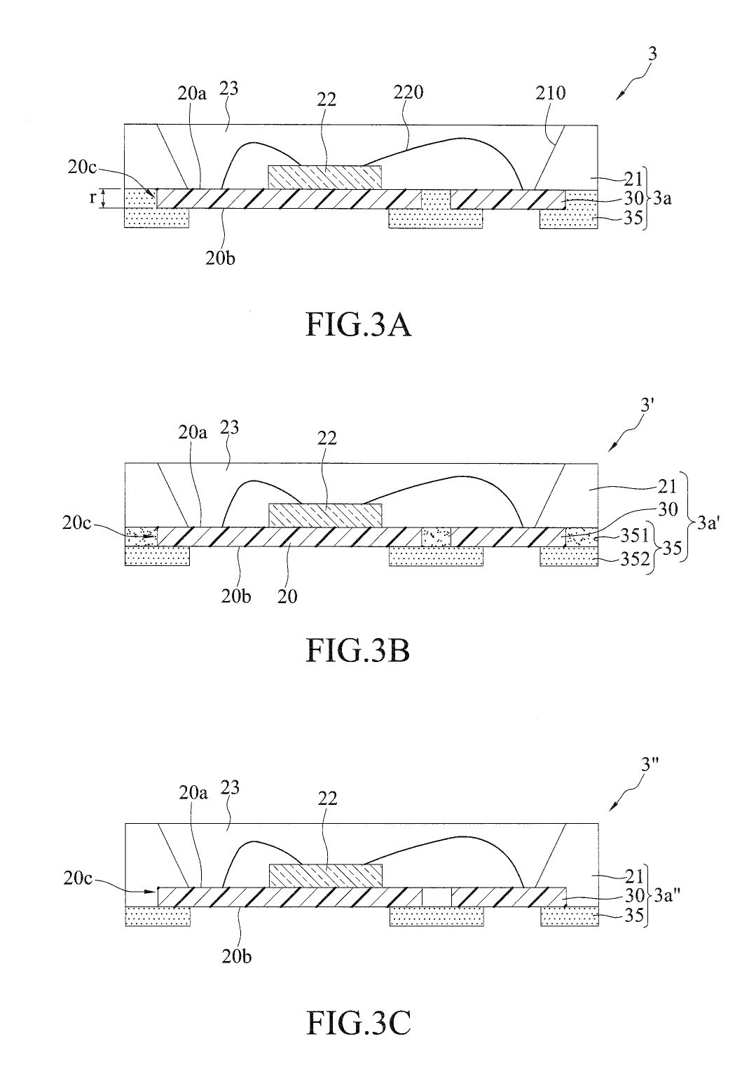

FIGS. 3A-3C are schematic cross-sectional views of different types of light emitting packages in accordance with a second preferred embodiment of the present invention. The second embodiment differs from the first embodiment in that the conductive traces of the second embodiment are different from those of the first embodiment.

In the light emitting package 3, 3′, 3″ (or carrier structure 3a, 3a′, 3a″) shown in FIGS. 3A-3C, the conductive trace is planer, and the thickness (r) of the conductive trace 30 is very small (about 10 μm). Therefore, the light emitting package 3, 3′, 3″ (or carrier structure 3a, 3a′, 3a″) can meet the low profile requirement.

In an embodiment, as shown in FIG. 3A, the insulative portion 35 is made of a photo sensitive dielectric material or a solder mask material.

As shown in FIG. 3B, the insulative portion 35′ comprises a first insulative layer 351 and a second insulative layer 352. The first insulative layer 351 is made of a photo sensitive dielectric material such as epoxy resin containing glass fiber or glass cloth. The second insulative layers 352 is made of a photo sensitive dielectric material or a solder mask material, and attached to a portion of the second surfaces 20b of the conductive traces 20 and the first insulative layer 351.

As shown in FIG. 3C, the insulative portion 35″ is made of a photo sensitive dielectric material or a solder mask material, and attached to a portion of the second surfaces 20b of the conductive traces 20. The receiving body 21 is formed on the insulative portion 35″ and a portion of the first surfaces 20a of the conductive traces 20, and further attached to the side surfaces 20c of the conductive traces 20.

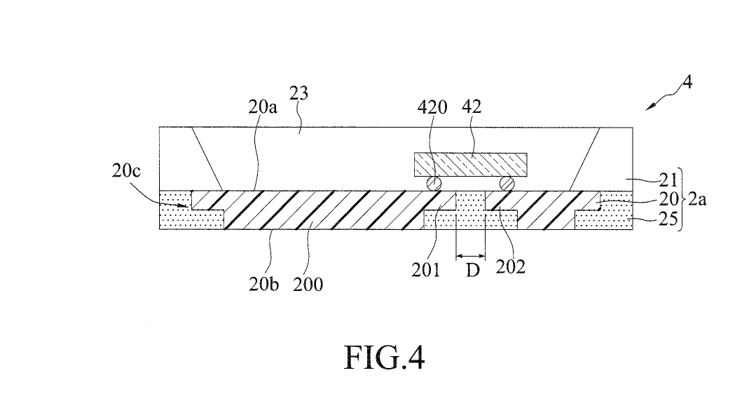

FIG. 4 is a schematic cross-sectional view of a light emitting package 4 in accordance with a third preferred embodiment of the present invention. The third embodiment differs from the first and second embodiments in that the third embodiment uses the bonding method of the light emitting member.

As shown in FIG. 4, the light emitting member 42 is electrically connected to the conductive traces 20 via the plurality of conductive bumps 420 in a flip-chip manner.

In an embodiment, packaging substrate formed by the conductive traces 20 combined with the insulative portion (not designated by a reference numeral) is used to carry the light emitting member 22, so as to reduce the distance D between two electrical connecting pads 201, 202 of the conductive trace 20, and the carrier structure 2a can be used in the flip-chip fabricating process. In comparison with a conventional lead frame, which cannot be used in the flip-chip fabricating process, the carrier structure 2a according to the present invention can be used in various applications.

In an embodiment, an additional layer (e.g., a surface treatment surface) can be formed on the conductive traces 20. The surface treatment layer includes gold, silver, tin, and/or organic solderability preservative (OSP).

In summary, the light emitting package and the carrier structure according to the present invention utilize the conductive trace to replace the conventional lead frame as the carrier for light emitting members, such that it is possible to meet the low profile requirement as well as to increase heat transmission efficiency. Moreover, supporting strength for the packaging substrate formed by the conductive traces combined with the insulative portion to carry the light emitting member is greatly enhanced through secured attachment to the insulative portion against the conductive traces.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A light emitting package, comprising:
a plurality of conductive traces each having a first surface, a second surface opposing the first surface, and a side surface abutting the first and second surfaces;
an insulative portion combined with the conductive traces to form a packaging substrate;
a receiving body formed on the packaging substrate and having an opening for a plurality of the first surfaces to be exposed therefrom;
at least a light emitting member disposed on the packaging substrate via the opening and electrically connected with the conductive traces; and
an encapsulant formed in the opening to encapsulate the light emitting member.

2. The light emitting package of claim 1, wherein each of the conductive trace is planer or in a concave-convex structure.

3. The light emitting package of claim 1, wherein the insulative portion is attached to the side surface of each of the conductive traces.

4. The light emitting package of claim 3, wherein the insulative portion is attached to a portion of the second surface of each of the conductive traces.

5. The light emitting package of claim 1, wherein the insulative portion is attached to a portion of the second surface of each of the conductive traces.

6. The light emitting package of claim 5, wherein the receiving body is attached to the side surface of each of the conductive traces.

7. The light emitting package of claim 1, wherein the insulative portion comprises a first insulative layer attached to the side surface of each of the conductive traces, and a second insulative layer attached to a portion of the second surface of each of the conductive traces.

8. The light emitting package of claim 7, wherein the second insulative layer is a solder mask layer.

9. The light emitting package of claim 1, wherein the insulative portion is made of silicon, epoxy resin, dielectric material or solder mask material.

10. The light emitting package of claim 9, wherein the insulative portion is made of a photo sensitive dielectric material.

11. The light emitting package of claim 1, wherein the receiving body and the insulative portion are made of different materials.

12. The light emitting package of claim 1, wherein the receiving body and the insulative portion are made of the same material.

13. The light emitting package of claim 1, wherein the light emitting member is electrically connected with the conductive traces by wire bonding or flip-chip method.

14. The light emitting package of claim 1, further comprising a surface treatment layer formed on the conductive traces.

15. A carrier structure, comprising:
a plurality of conductive traces each having a first surface, a second surface opposing the first surface, and a side surface abutting the first and second surfaces;
an insulative portion combined with the conductive traces to form a packaging substrate; and
a receiving body formed on the substrate and having an opening for a portion of the first surfaces of the conductive traces to be exposed therefrom.

16. The carrier structure of claim 15, wherein each of the conductive traces is planer or in a concave-convex structure.

17. The carrier structure of claim 15, wherein the insulative portion is attached to the side surface of each of the conductive trace.

18. The carrier structure of claim 17, wherein the insulative portion is attached to a portion of the second surface of each of the conductive traces.

19. The carrier structure of claim 15, wherein the insulative portion is attached to a portion of the second surface of each of the conductive traces.

20. The carrier structure of claim 19, wherein the receiving body is attached to the side surface of each of the conductive traces.

21. The carrier structure of claim 15, wherein the insulative portion comprises a first insulative layer attached to the side surface of each of the conductive traces, and a second insulative layer attached to a portion of the second surface of each of the conductive traces.

22. The carrier structure of claim 21, wherein the second insulative layer is a solder mask layer.

23. The carrier structure of claim 15, wherein the insulative portion is made of silicon, epoxy resin, dielectric material or solder mask material.

24. The carrier structure of claim 23, wherein the insulative portion is made of a photo sensitive dielectric material.

25. The carrier structure of claim 15, wherein the receiving body and the insulative portion are made of different materials.

26. The carrier structure of claim 15, wherein the receiving body and the insulative portion are made of the same material.

27. The carrier structure of claim 15, further comprising a surface treatment layer formed on the conductive traces.
